(19) United States
(12) Patent Application Publication
(10) Pub. No.: US 2019/0296082 A1
(43) Pub. Date: Sep. 26, 2019

(54) MEMORY DEVICE

(71) Applicant: Toshiba Memory Corporation, Tokyo (JP)

(72) Inventor: Tadashi IGUCHI, Yokkaichi Mie (JP)

(73) Assignee: Toshiba Memory Corporation, Tokyo (JP)

(21) Appl. No.: 16/137,426

(22) Filed: Sep. 20, 2018

(30) Foreign Application Priority Data
Mar. 23, 2018 (JP) 2018-055415

(51) Int. Cl. H01L 27/24; H01L 45/00

(52) U.S. Cl. CPC H01L 27/2436; H01L 45/145; H01L 45/1253; H01L 45/1616; H01L 27/2481

(57) ABSTRACT

A memory device according to an embodiment includes: a first conductive layer extending in a first direction; a second conductive layer extending in the first direction; a third conductive layer extending in a second direction intersecting the first direction, the third conductive layer being provided between the first conductive layer and the second conductive layer; a fourth conductive layer that extends in the second direction and is provided between the first conductive layer and the second conductive layer; a first connection portion connecting a first end portion of the third conductive layer and a first end portion of the fourth conductive layer; and a first resistance change layer provided between the first conductive layer and the third conductive layer.

### CROSS-REFERENCE TO RELATED APPLICATION

This application is based upon and claims the benefit of priority from Japanese Patent Application No. 2018-055415, filed on Mar. 23, 2018, the entire contents of which are incorporated herein by reference.

### FIELD

Embodiments described herein relate generally to memory devices.

### BACKGROUND

In a resistive random access memory, a voltage is applied to a resistance change layer of a memory cell such that a current flows, thereby changing the resistance change layer between a high-resistance state and a low-resistance state. For example, in a case in which the high-resistance state is defined as data “0” and the low-resistance state is defined as data “1”, the memory cell can store 1-bit data “0” or “1”.

A memory cell array with a three-dimensional structure in which memory cells are three dimensionally arranged is applied in order to increase the degree of integration of the resistive random access memory. In addition, a memory cell array with a three-dimensional structure in which the size of a memory cell is reduced is expected to be achieved in order to increase the degree of integration of the resistive random access memory.

### BRIEF DESCRIPTION OF THE DRAWINGS

FIG. 1 is a block diagram illustrating a memory device according to a first embodiment;

FIG. 2 is an equivalent circuit diagram illustrating a memory cell array of the memory device according to the first embodiment;

FIGS. 3A and 3B are cross-sectional views schematically illustrating the memory cell array of the memory device according to the first embodiment;

FIG. 4 is a top view schematically illustrating the memory cell array of the memory device according to the first embodiment;

FIGS. 5A and 5B are cross-sectional views schematically illustrating the memory device that is being manufactured in a memory device manufacturing method according to the first embodiment;

FIGS. 6A and 6B are cross-sectional views schematically illustrating the memory device that is being manufactured in the memory device manufacturing method according to the first embodiment;

FIGS. 7A and 7B are cross-sectional views schematically illustrating the memory device that is being manufactured in the memory device manufacturing method according to the first embodiment;

FIGS. 8A and 8B are cross-sectional views schematically illustrating the memory device that is being manufactured in the memory device manufacturing method according to the first embodiment;

FIGS. 9A and 9B are cross-sectional views schematically illustrating the memory device that is being manufactured in the memory device manufacturing method according to the first embodiment;

FIGS. 10A and 10B are cross-sectional views schematically illustrating the memory device that is being manufactured in the memo device manufacturing method according to the first embodiment;

FIGS. 11A and 11B are cross-sectional views schematically illustrating the memory device that is being manufactured in the memory device manufacturing method according to the first embodiment;

FIGS. 12A and 12B are cross-sectional views schematically illustrating the memory device that is being manufactured in the memory device manufacturing method according to the first embodiment;

FIGS. 13A and 13B are cross-sectional views schematically illustrating a memory cell array of a memory device according to a first comparative example;

FIGS. 14A and 14B are diagrams illustrating the function and effect of the first embodiment;

FIGS. 15A and 15B are cross-sectional views schematically illustrating a memory cell array of a memory device according to a second embodiment;

FIGS. 16A and 16B are cross-sectional views schematically illustrating the memory device that is being manufactured in a memory device manufacturing method according to the second embodiment;

FIGS. 17A and 17B are cross-sectional views schematically illustrating the memory device that is being manufactured in the memory device manufacturing method according to the second embodiment;

FIGS. 18A and 18B are cross-sectional views schematically illustrating the memory device that is being manufactured in the memory device manufacturing method according to the second embodiment; and

FIGS. 19A and 19B are cross-sectional views schematically illustrating a memory cell array of a memory device according to a third embodiment.

### DETAILED DESCRIPTION

A memory device according to an embodiment includes: a first conductive layer extending in a first direction; a second conductive layer extending in the first direction; a third conductive layer that extends in a second direction intersecting the first direction and is provided between the first conductive layer and the second conductive layer; a fourth conductive layer that extends in the second direction and is provided between the first conductive layer and the second conductive layer; a first connection portion connecting a first end portion of the third conductive layer and a first end portion of the fourth conductive layer; and a first resistance change layer provided between the first conductive layer and the third conductive layer.

Hereinafter, memory devices according to embodiments will be described with reference to the drawings. In the following description, for example, the same or similar members are denoted by the same reference numerals and the description of the members that have been described once will not be repeated.

### First Embodiment

A memory device according to a first embodiment includes: a first conductive layer extending in a first direction; a second conductive layer extending in the first direction; a third conductive layer extending in a second direction intersecting the first direction, at least a portion of the third conductive layer being provided between the first conductive layer and the second conductive layer; a fourth conductive layer extending in the second direction, at least a portion of the fourth conductive layer being provided between the first conductive layer and the second conductive layer; a first connection portion connecting a first end portion of the third conductive layer and a first end portion of the fourth conductive layer; and a first resistance change layer provided between the first conductive layer end the third conductive layer.

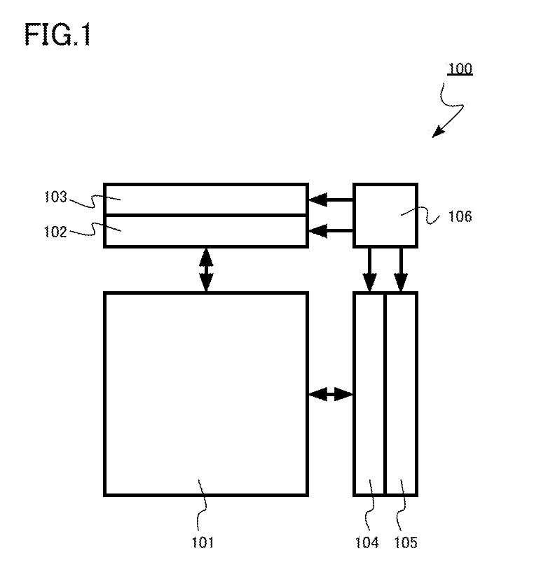

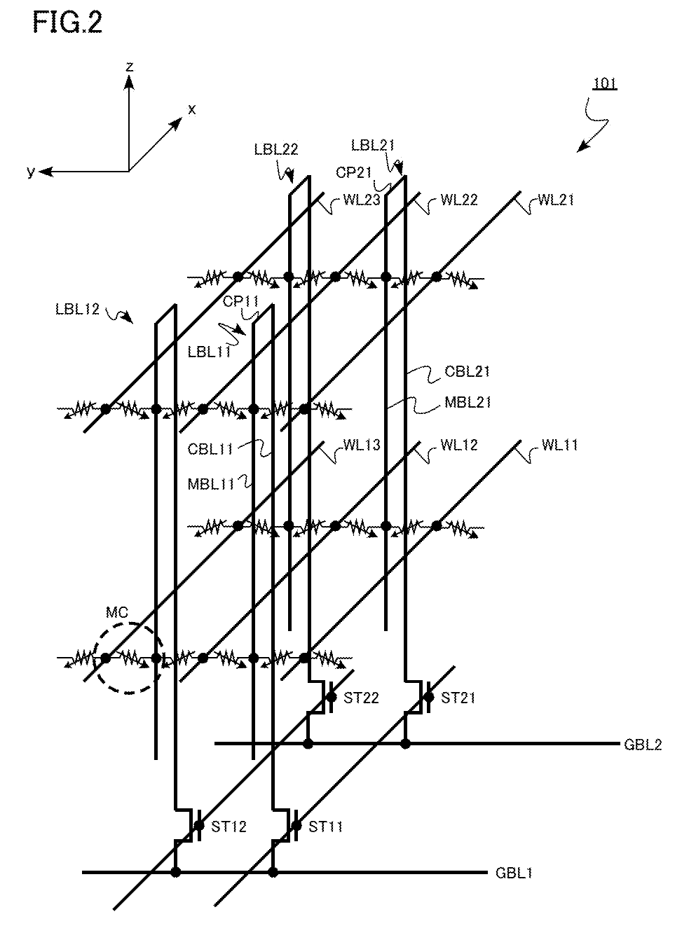

FIG. 1 is a block diagram illustrating the memory device according to the first embodiment. FIG. 2 is an equivalent circuit diagram illustrating a memory cell array of the memory device according to the first embodiment. FIG. 2 schematically illustrates the wiring structure of the memory cell array.

A memory device 100 according to the first embodiment is a resistive random access memory (ReRAM). The memory cell array according to the first embodiment has a three-dimensional structure in which memory cells are three-dimensionally arranged. The degree of integration of the memory device 100 is improved by the three-dimensional structure.

As illustrated in FIG. 1, the memory device 100 includes a memory cell array 101, a word line driver circuit 102, a row decoder circuit 103, a sense amplifier circuit 104, a column decoder circuit 105, and a control circuit 106.

As illustrated in FIG. 2, a plurality of memory cells MC are three-dimensionally arranged in the memory cell array 101. In FIG. 2, a region surrounded by a dashed line corresponds to one memory cell MC.

The memory cell array 101 includes, for example, a plurality of word lines WL (WL11, WL12, WL13, WL21, WL22, WL23) and a plurality of local bit lines LBL (LBL11, LBL12, LBL21, and LBL22). The word line WL extends in the x direction. The local bit line LBL extends in the z direction.

Each local bit line LBL has a structure in which the local bit line LBL is folded in an upper part of the memory cell array 101. Hereinafter, a portion having the memory cell is referred to as a memory bit line MBL, a portion that does not have the memory cell and functions as a connection wire is referred to as a connection bit line CBL, and a portion that connects the memory bit line MBL and the connection bit line CBL in the upper part of the memory cell array 101 is referred to as a connection portion CP. For example, the local bit line LBL11 includes a memory bit line MBL11, a connection bit line CBL11, and a connection portion CPU as illustrated in FIG. 2.

The word line WL and the memory bit line MBL intersect each other at a right angle. The word line WL and the connection bit line CBL intersect each other at a fight angle. The memory cell MC is provided at the intersection between the word line WL and the memory bit line MBL. A resistance change layer is provided at the intersection between the word line WL and the memory bit line MBL.

The word line WL11 is an example of a first conductive layer, the word line WL12 is an example of a second conductive layer, the memory bit line MBL11 is an example of a third conductive layer, the connection bit line CBL11 is an example of a fourth conductive layer, a memory bit line MBL21 is an example of a fifth conductive layer, a connection bit line CBL21 is an example of a sixth conductive layer, the connection portion CP11 is an example of a first connection portion, and a connection portion CP21 is an example of a second connection portion. In addition, the x direction is an example of a first direction, the y direction is an example of a third direction, and the z direction is an example of a second direction. The x direction, the y direction, and the z direction are perpendicular to each other.

The plurality of word lines WL are electrically connected to the row decoder circuit 103. The plural of local bit lines LBL are connected to the sense amplifier circuit 104. Selection transistors ST (ST11, ST21, ST12, and ST22) and global bit lines GBL (GBL1, GBL2) are provided between the plurality of local bit lines LBL and the sense amplifier circuit 104. The selection transistor ST has a function of selecting a desired local bit line LBL.

The row decoder circuit 103 has a function of selecting the word line WL on the basis of an input row address signal. The word line driver circuit 102 has a function of applying a predetermined voltage to the word WL selected by the row decoder circuit 103.

The column decoder circuit 105 has a function of selecting the local bit line LBL on the basis of an input column address signal. The sense amplifier circuit 104 has a function of applying predetermined voltage to the local bit line LBL selected by the column decoder circuit 105. In addition, the sense amplifier circuit 104 has a function of detecting the current flowing between the selected word line WL and the selected local bit line LBL and amplifying the current.

The control circuit 106 has a function of controlling the word line driver circuit 102, the row decoder circuit 103, the sense amplifier circuit 104, the column decoder circuit 105, and other circuits (not illustrated).

Circuits, such as the word line driver circuit 102, the row decoder circuit 103, the sense amplifier circuit 104, the column decoder circuit 105, and the control circuit 106 are electronic circuits. For example, each of the circuits includes a transistor using a semiconductor layer (not illustrated) and a wiring layer (not illustrated).

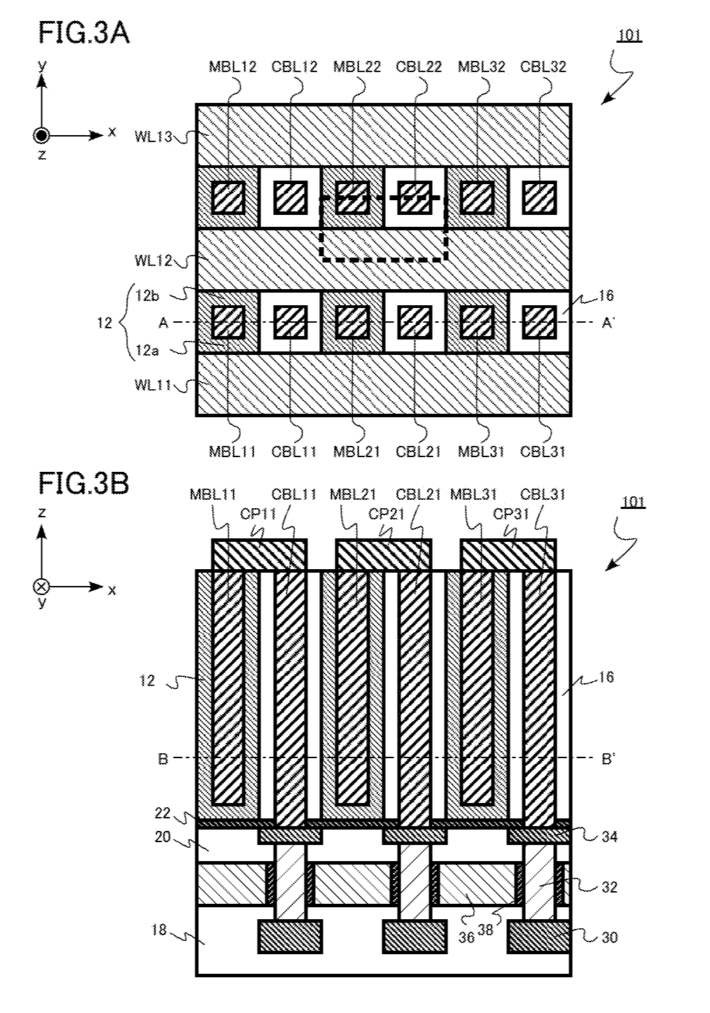

FIGS. 3A and 3B are cross-sectional views schematically illustrating the memory cell array 101 of the memory device 100 according to the first embodiment. FIG. 3A is an xy cross-sectional view illustrating the memory cell array 101. FIG. 3B is an xz cross-sectional view illustrating the memory cell array 101. FIG. 3A is a cross-sectional view taken along the line BB′ of FIG. 3B and FIG. 3B is a cross-sectional view taken along the line AA′ of FIG. 3A. In FIG. 3A, a region surrounded by the dashed line corresponds to one unit cell of the memory cell.

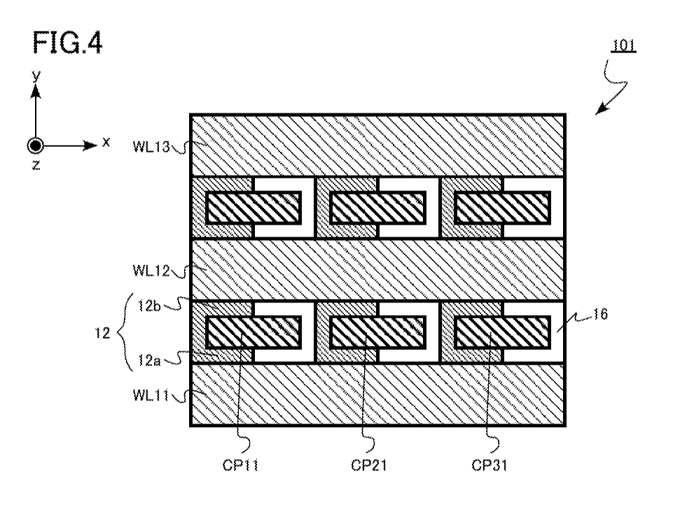

FIG. 4 is a top view schematically illustrating the memory cell array 101 of the memory device 100 according to the first embodiment. FIG. 4 is a top view of FIG. 3B.

The memory cell array 101 includes the word line WL11 (first conductive layer), the word line WL12 (second conductive layer), the word line WL13, the memory bit line MBL11 (third conductive layer), the memory bit line MBL21 (fifth conductive layer), a memory bit line MBL31, the connection bit line CBL11 (fourth conductive layer), the connection bit line CBL21 (sixth conductive layer), a connection bit line CBL31, the connection portion CP11 (first connection portion), the connection portion CP21 (second connection portion), and a connection portion CP31. In addition, the memory cell array 101 includes a resistance change layer 12, a sidewall insulating layer 16 (insulating layer), an interlayer insulating layer 18, an interlayer insulating layer 20, and a stopper film 22. Furthermore, the memory cell array 101 includes a drain electrode 30 (first electrode), a semiconductor layer 32, a source electrode 34 (second electrode), a gate electrode 36, and a gate insulating film 38.

Hereinafter, in some cases, for example, the word line WL11 (first conductive layer), the word line WL12 (second conductive layer), and the word line WL13 are simply generically referred to as word lines WL. In addition, in some cases, for example, the memory bit line MBL11 (third conductive layer), the memory bit line MBL21 (fifth conductive layer), and the memory bit line MBL31 are simply generically referred to as memory bit lines MBL. Further, in some cases, for example, the connection bit line CBL11 (fourth conductive layer), the connection bit line CBL21 (sixth conductive layer), and the connection bit line CBL31 simply generically referred to as connection bit lines CBL. Furthermore, in some cases, for example, the connection portion CP11 (first connection portion), the connection portion CP21 (second connection portion), and the connection portion CP31 are simply generically referred to as connection portions CP.

The word line WL is a conductive layer. The word line WL extends in the x direction.

The word line WL is made of, for example, metal. The word line WL is made of, for example, tungsten (W), or titanium nitride (TiN). The word line WL may be made of other metal materials, a metal semiconductor compound, or a conductive material such as a semiconductor.

The memory bit line MBL and the connection bit line CBL are conductive layers. The memory bit line MBL and the connection bit line CBL extend in the z direction. At least a portion of each of the memory bit line MBL and the connection bit line CBL is located between two word lines. For example, at least a portion of each of the memory bit line MBL11 and the connection bit line CBL11 is located between the word line WL11 and the word line WL12.

The memory bit line MBL and the connection bit line CBL are made of, for example, metal. The memory bit line MBL and the connection bit line CBL are made of, for example, tungsten (W), titanium nitride (TiN), or copper (Cu). The memory bit line MBL and the connection bit line CBL may be made of other metal materials, a metal semiconductor compound, or a conductive material such as a semiconductor.

The connection portion CP connects the memory bit line MBL and the connection bit line CBL. The connection portion CP connects a first end portion of the memory bit line MBL and a first end portion of the connection bit line CBL. The connection portion CP comes into contact with the first end portion of the memory bit line MBL. The connection portion CP comes into contact with the first end portion of the connection bit line CBL. The connection portion CP electrically connects the memory bit line MBL and the connection bit line CBL.

The connection portion CP is made of, for example, metal. The connection portion CP is made of, for example, tungsten (W), titanium nitride (TiN), or copper (Cu). The connection portion CP may be made of other metal materials, a metal semiconductor compound, or a conductive material such as a semiconductor.

In FIG. 3B, an upper end portion of the memory bit line MBL is referred to as the first end portion and a lower end portion of the memory bit line BL is referred to as a second end portion. In FIG. 3B, an upper end portion of the connection bit line CBL is referred to as the first end portion and a lower end portion of the connection bit line CBL is referred to as a second end portion.

The memory bit line MBL, the connection portion CP, and the connection bit line CBL form one local bit line LBL. For example, the memory bit line MBL11, the connection portion CP11, the connection bit line CBL11 form one local bit line LBL11 (see FIG. 2).

The local bit lines LBL are provided in the x direction between at a predetermined pitch between two word lines WL. For example, at least a portion of each of the memory bit line MBL21 and the connection bit line CBL21 is located between the word line WL11 and the word line WL12. The connection bit line CBL11 is provided between the memory bit line MBL11 and the memory bit line MBL21. The memory bit line MBL21 is provided between the connection bit line CBL11 and the connection bit line CBL21.

The pitch between the word lines WL in the y direction is, for example, equal to or greater than 50 nm and equal to or less than 200 nm. The pitch between the local bit lines LBL in the x direction is, for example, equal to or greater than 50 nm and equal to or less than 200 nm.

The resistance change layer 12 is provided so as to surround the memory bit line MBL. The resistance change layer 12 is provided between the word line WL and the memory bit line MBL. For example, the resistance change layer 12 (first resistance change layer) is provided between the word line WL11 and the memory bit line MBL11. For example, the resistance change layer 12 (second resistance change layer) is provided between the word line WL11 and the memory bit line MBL21.

The resistance change layer 12 includes a first region 12a and a second region 12b. For example, the first region 12a is provided between the word line WL11 and the memory bit line MBL11. The second region 12b is provided between the word line WL12 and the memory bit line MBL11. The first region 12a and the second region 12b are continuous with each other.

The resistance change layer 12 has a function of storing data using a change in resistance state. In addition, a voltage or a current can be applied to the resistance change layer 12 to rewrite data. A voltage or a current is applied to the resistance change layer 12 to change the resistance change layer 12 between a high-resistance state (reset state) and a low-resistance state (set state) For example, the high-resistance state is defined as data “0” and the low-resistance state is defined as data “1”. The memory cell MC stores 1-bit data “0” or “1”.

The material forming the resistance change layer 12 is not particularly limited as long as it has a function of storing data using a change in resistance state. The resistance change layer 12 includes, for example, metal oxide. The resistance change layer 12 is, for example, a stacked film of two different types of metal oxide.

The sidewall insulating layer 16 is provided so as to surround the connection bit line CBL. The sidewall insulating layer 16 is provided between the connection bit line CBL and the word line WL. The sidewall insulating layer 16 is provided between the connection bit line CBL and the memory bit line MBL. The sidewall insulating layer 16 is provided between the connection bit line CBL and the resistance change layer 12.

The sidewall insulating layer 16 is made of oxide or oxynitride. The sidewall insulating layer 16 is made of, for example, silicon oxide.

The drain electrode 30 (first electrode), the semiconductor layer 32, the source electrode 34 (second electrode), the gate electrode 36, and the gate insulating film 38 are provided below the word line WL, the memory bit line MBL, and the connection bit line CBL. The drain electrode 30 (first electrode), the semiconductor layer 32, the source electrode 34 (second electrode), the gate electrode 36, and the gate insulating film 38 form the selection transistor ST.

The selection transistor ST is, for example, a surrounded gate transistor (SGT).

The drain electrode 30 is made of, for example, metal. The drain electrode 30 extends in the y direction. The drain electrode 30 is the global bit line GBL.

The semiconductor layer 32 is provided between the drain electrode 30 and the second end portion of the connection bit line CBL. For example, the semiconductor layer 32 is provided between the drain electrode 30 and the second end portion of the connection bit line CBL11. The semiconductor layer 32 is made of, for example, polysilicon.

The source electrode 34 is provided between the semiconductor layer 32 and the second end portion of the connection bit line CBL. The source electrode 34 is electrically connected to the second end portion of the connection bit line CBL. For example, the source electrode 34 is electrically connected to the second end portion of the connection bit line CBL11.

The gate electrode 36 is made of, for example, metal, a metal semiconductor compound, or a semiconductor. The gate electrode 36 is made of, for example, titanium nitride (TiN). The gate electrode 36 extends in the x direction.

The gate insulating film 38 is provided between the semiconductor layer 32 and the gate electrode 36. The gate insulating film 38 is made of oxide or oxynitride. The gate insulating film 38 is made of, for example, silicon oxide.

The drain electrode 30 (first electrode), the semiconductor layer 32, the source electrode 34 (second electrode), the gate electrode 36 and the gate insulating film 38 are provided in the interlayer insulating layer 18 or the interlayer insulating layer 20. The interlayer insulating layer 18 and the interlayer insulating layer 20 are made of, for example, silicon oxide.

The stopper film 22 is provided between the interlayer insulating layer 20 and the resistance change layer 12 and between the interlayer insulating layer 20 and the sidewall insulating layer 16. The stopper film 22 is made of, for example, nitride. The stopper film 22 is made of, for example, silicon nitride film.

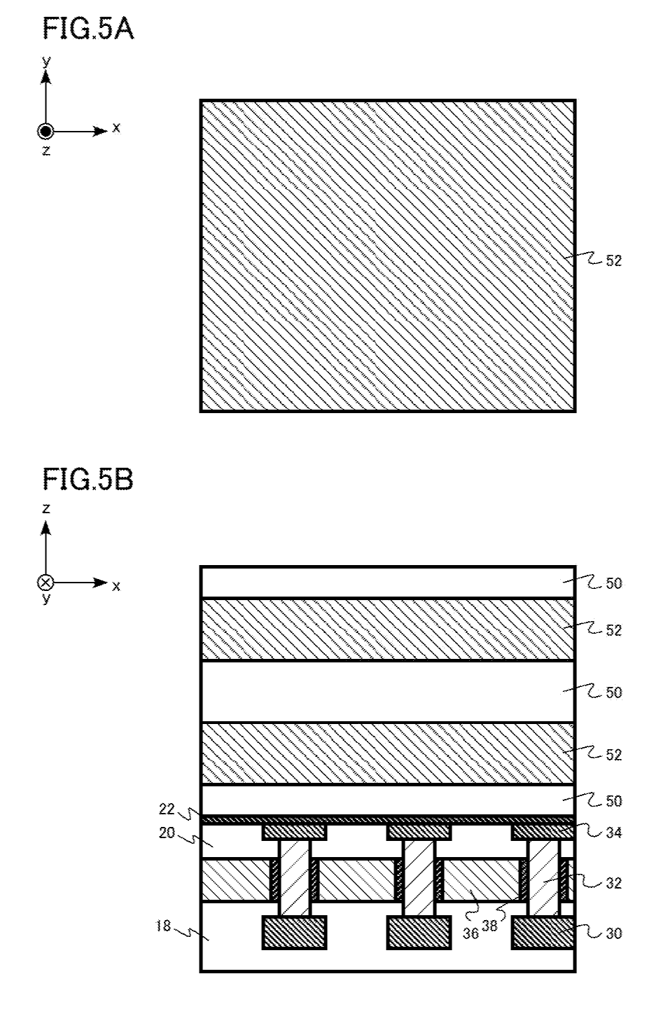

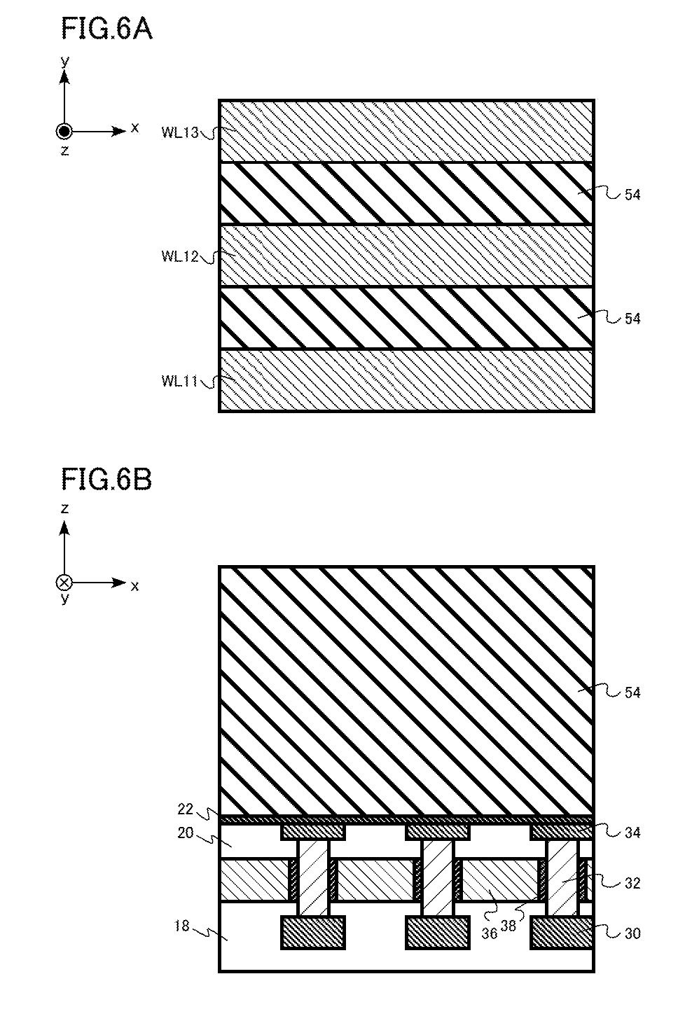

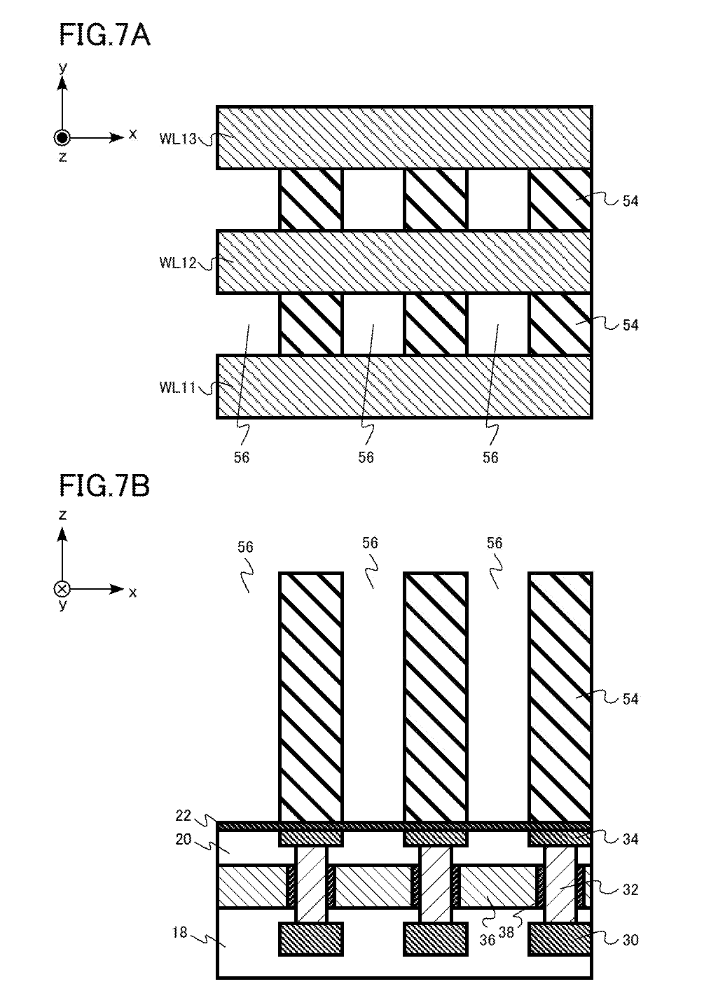

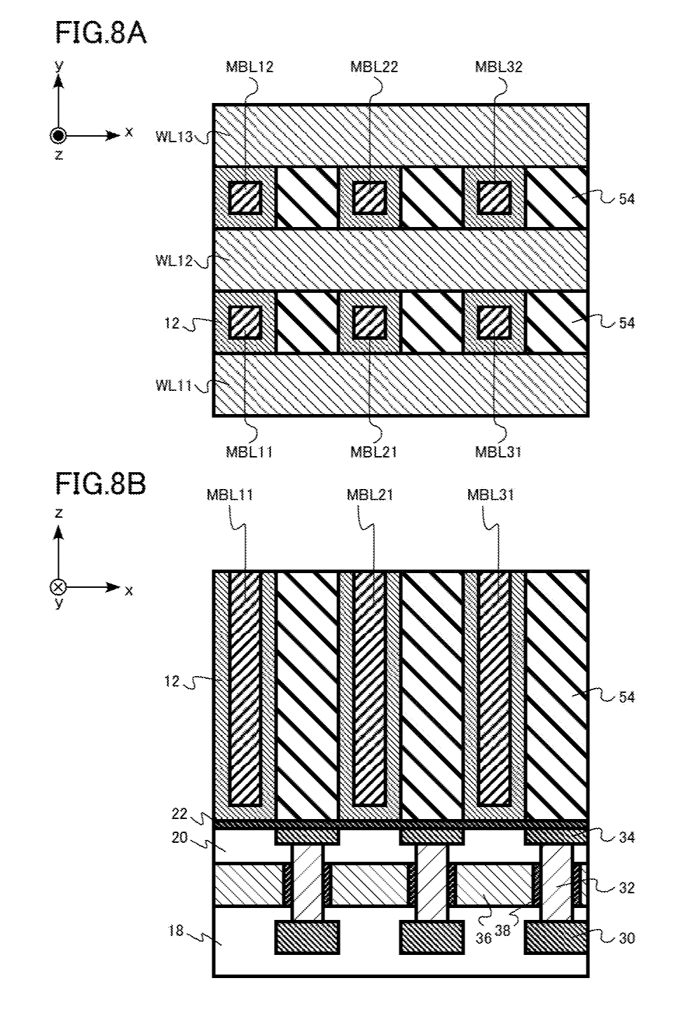

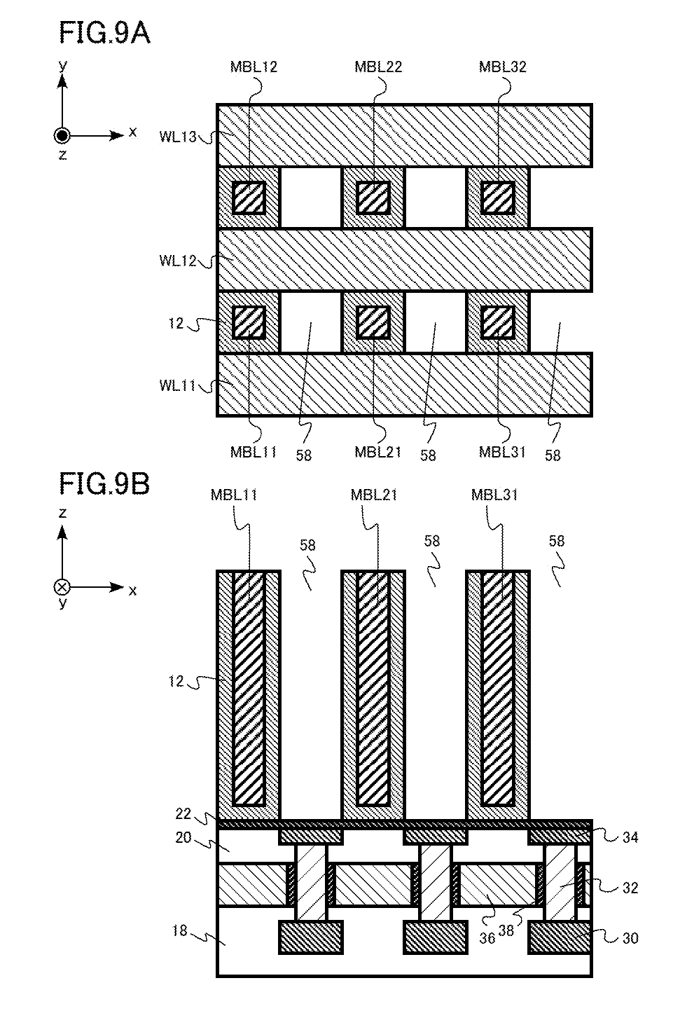

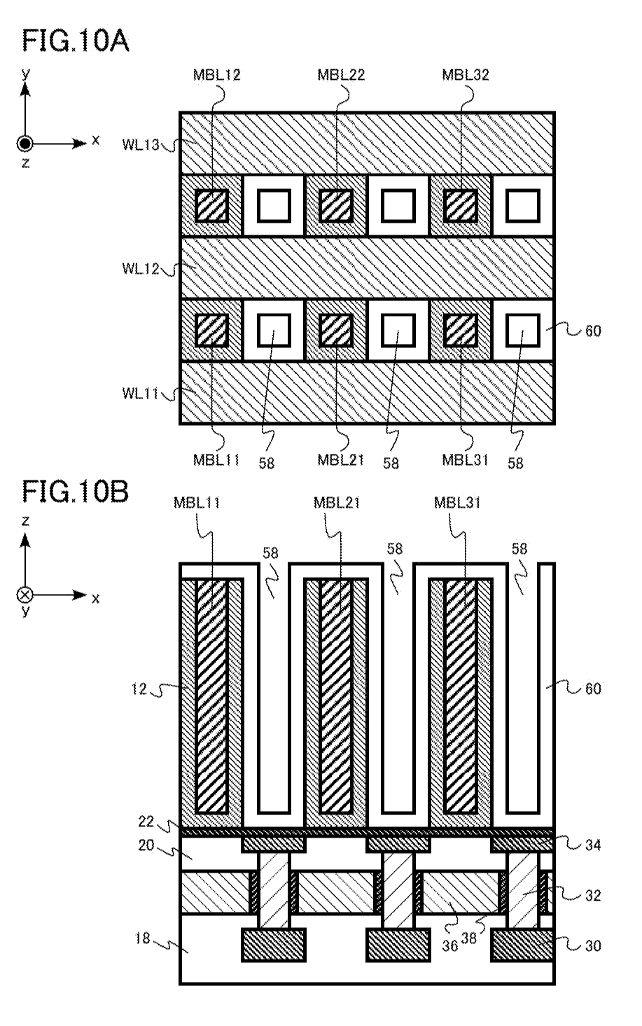

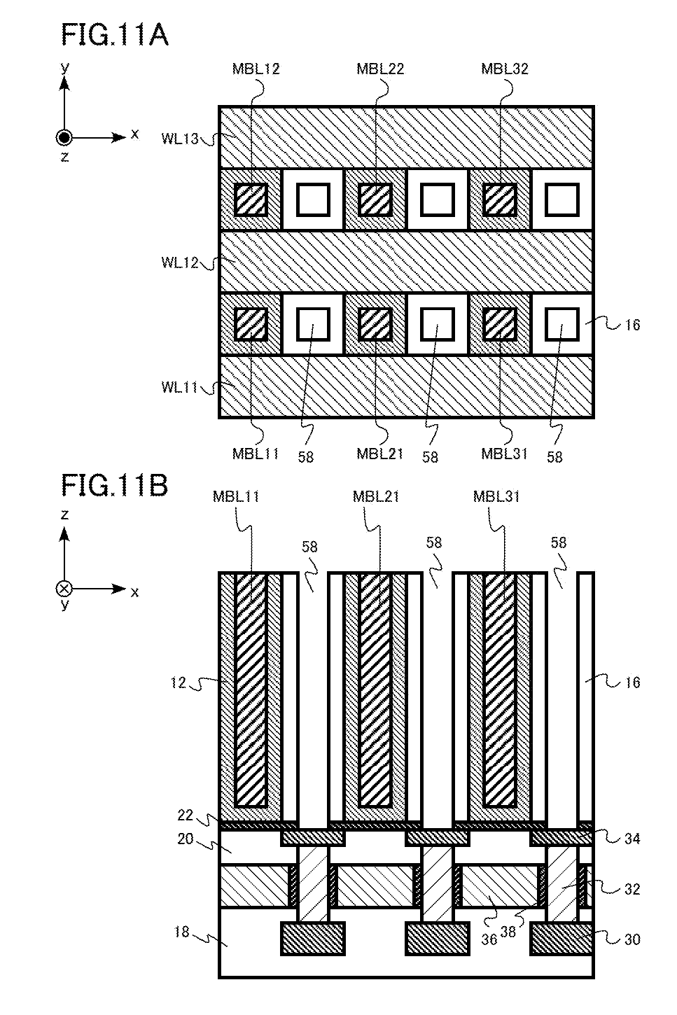

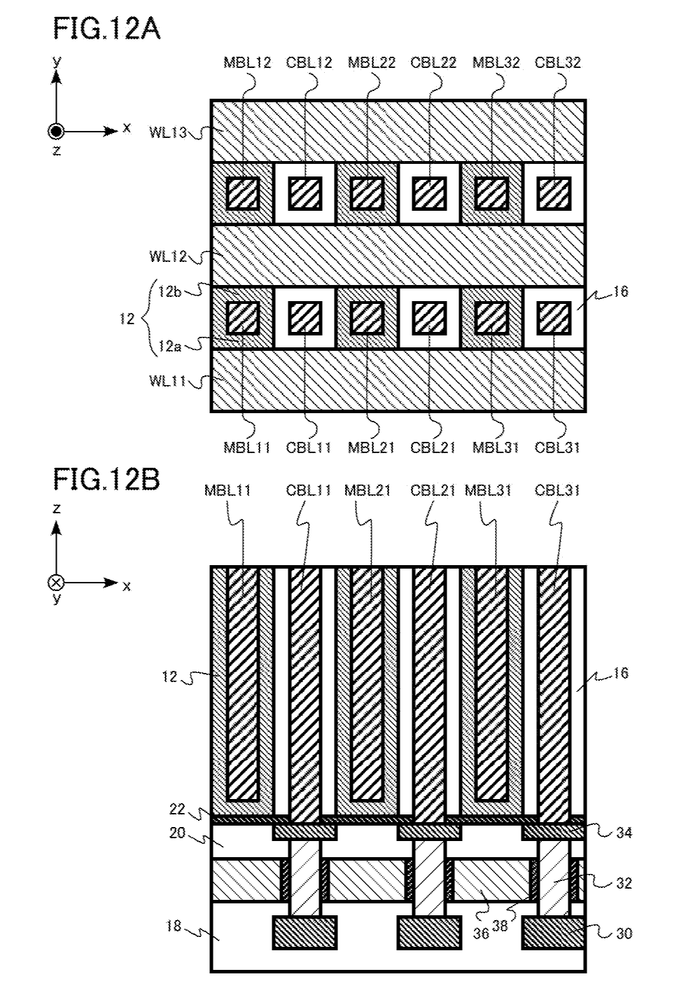

Next, a method for manufacturing the memory device according to the first embodiment will be described. FIG. 5A, FIG. 5B, FIG. 6A, FIG. 6B, FIG. 7A, FIG. 7B, FIG. 8A, FIG. 8B, FIG. 9A, FIG. 9B, FIG. 10A, FIG. 10B, FIG. 11A, FIG. 11B, FIG. 12A, and FIG. 12B are cross-sectional views schematically illustrating the memory device that is being manufactured in the memory device manufacturing method according to the first embodiment. FIG. 5A, FIG. 6A, FIG. 7A, FIG. 8A, FIG. 9A, FIG. 10A, FIG. 11A, and FIG. 12A are cross-sectional views illustrating the portion corresponding to FIG. 3A. FIG. 5B, FIG. 6B, FIG. 7B, FIG. 8B, FIG. 9B, FIG. 10B, FIG. 11B, and FIG. 12B are cross-sectional views illustrating the portion corresponding to FIG. 3B.

First, the selection transistor ST is formed on a substrate (not illustrated) by a known process technique. The selection transistor ST includes the drain electrode 30, the semiconductor layer 32, the source electrode 34, the gate electrode 36, and the gate insulating film 38. The selection transistor ST is provided in the interlayer insulating layer 18 or the interlayer insulating layer 20.

Then, the stopper film 22 is formed on the interlayer insulating layer 20 and the source electrode 34. Then, an insulating film 50 and a conductive film 52 are alternately stacked on the stopper film 22 (FIGS. 5A and 5B). The insulating film 50 and the conductive film 52 are deposited by, for example, a known chemical vapor deposition method (CVD method).

Then, the insulating film 50 and the conductive film 52 are etched to form a groove that is parallel to the xz plane. The groove is formed by, for example, a known lithography method and anisotropic dry etching. In a case in which the insulating film 50 and the conductive film 52 are etched, the etching is stopped by the stopper film 22. The conductive film 52 is pattered to form the word line WL.

Then, the groove is filled with a sacrifice film 54 (FIGS. 6A and 6B). The sacrifice film 54 is made of, for example, amorphous silicon. The sacrifice film 54 is deposited by, for example, a known CVD method.

Then, the sacrifice film 54 is etched to form opening portions 56 (FIGS. 7A and 7B). In a case in which the sacrifice film 54 is etched, the etching is stopped by the stopper film 22. The opening portion 56 is formed by, for example, a known lithography method and anisotropic dry etching.

Then, the resistance change layer 12 is formed in the opening portion 56. In addition, the opening portion 56 is filled with a conductive layer to form the memory bit line MBL (FIGS. 8A and 8B). The formation of the resistance change layer 12 and the filling of the opening portion 56 with the conductive layer are performed by, for example, a known CVD method.

Then, the sacrifice film 54 is etched to form an opening portion 58 (FIGS. 9A and 9B). In a case in which the sacrifice film 54 is etched, the etching is stopped by the stopper film 22. The sacrifice film 54 is etched by, for example, wet etching.

Then, an insulating film 60 is deposited in the opening portion 58 (FIGS. 10A and 10B). The insulating film 60 is made of, for example, silicon oxide. The insulating film 60 is deposited by, for example, a known CVD method.

Then, the insulating film 60 located at the bottom of the opening portion 58 is removed (FIGS. 11A and 11B). The source electrode 34 is exposed through the bottom of the opening portion 58. The insulating film 60 located at the bottom of the opening portion 58 is removed by anisotropic etching. The insulating film 60 on the side surface of the opening portion 58 remains and the sidewall insulating layer 16 is formed.

Then, the opening portion 58 is filled with a conductive layer to form the connection bit line CBL (FIGS. 12A and 12B). The connection bit line CBL comes into contact with the source electrode 34. The filling of the opening portion 58 with the conductive layer is performed by, for example, a known CVD method.

Then, a conductive film is deposited and patterned to form the connection portion CP.

The memory cell array 101 of the memory device 100 according to the first embodiment illustrated in FIG. 3A, FIG. 3B, and FIG. 4 is manufactured by the above-mentioned manufacturing method.

Next, the function and effect of the memory device 100 according to the first embodiment will be described.

It is preferable to reduce the size of the memory cell in order to increase the degree of integration of the resistive random access memory.

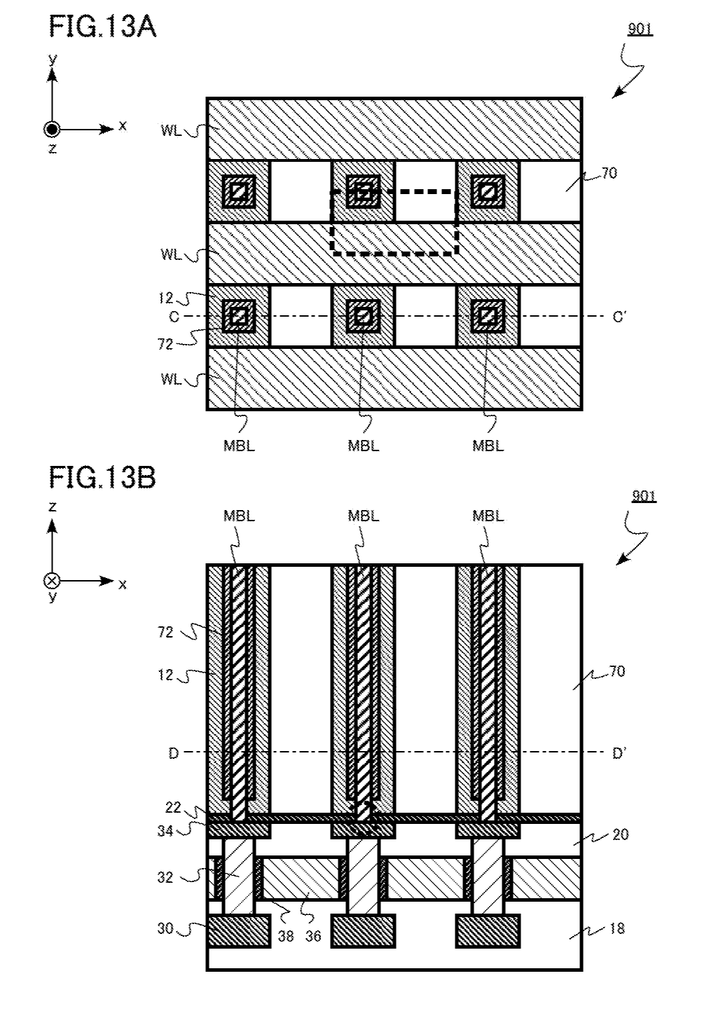

FIGS. 13A and 13B are cross-sectional views schematically illustrating a memory cell array 901 of a memory device according to a comparative example. FIG. 13A is an xy cross-sectional view illustrating the memory cell array 901. FIG. 13B is xz cross-sectional view illustrating the memory cell array 901. FIG. 13A is a cross-sectional view taken along the line DD′ of FIG. 13B and FIG. 13B is a cross-sectional view taken along the line CC′ of FIG. 13A. In FIG. 13A, a region surrounded by a dashed line corresponds to one unit cell of a memory cell.

The memory cell array 901 includes a plurality of word lines WL and a plurality of memory bit lines MBL. In addition the memory cell array 901 includes a resistance change layer 12, an insulating layer 70, a protective film 72, an interlayer insulating layer 18, an interlayer insulating layer 20, and a stopper film 22. Furthermore, the memory cell array 901 includes a drain electrode 30, a semiconductor layer 32, a source electrode 34, a gate electrode 35, and a gate insulating film 38.

The memory cell array 901 according to the comparative example differs from the memory cell array 101 according to the first embodiment in that it does not include the connection bit line CBL and the connection portion CP. In addition, the memory cell array 901 according to the comparative example differs from the memory cell array 101 according to the first embodiment in that the protective film 72 is provided between the memory bit line MBL and the resistance change layer 12.

In the memory cell array 901 according to the comparative example, the local bit line LBL is formed by only the memory bit line MBL. Therefore, the second end portion of the memory bit line MBL is connected to the source electrode 34 of the selection transistor ST. The insulating layer 70 is provided between the memory bit lines MBL.

In a case in which the memory cell array 901 is manufactured, it is necessary to remove the resistance change layer 12 on the source electrode 34 before the memory bit line MBL is formed in order to connect the memory bit line MBL to the source electrode 34. That is, it is necessary to remove the resistance change layer 12 located at the bottom of the opening portion for forming the memory bit line MBL.

The resistance change layer 12 located at the bottom of the opening portion is removed by anisotropic dry etching. In a case in which the resistance change layer 12 located at the bottom of the opening portion is removed, the protective film 72 is used to protect the resistance change layer 12 on the side surface of the opening portion from etching. The protective film 72 is, for example, a metal film.

The diameter of the bottom of the opening portion is reduced by the formation of the protective film 72. Therefore, the area of a connection portion (a region surrounded by a dashed line in FIG. 13B) between the memory bit line MBL and the source electrode 34 is reduced. As a result, a connection failure between the memory bit line MBL and the source electrode 34 is likely to occur.

In a case in which the diameter of the bottom of the opening portion is reduced, the aspect ratio of the opening portion increases. Therefore, an etching rate in a case in which the resistance change layer 12 located at the bottom of the opening portion and the protective film 72 are removed is reduced. As a result, it is difficult to etch the resistance change layer 12 located at the bottom of the opening portion and the protective film 72. From this point of view, a connection failure between the memory bit line MBL and the source electrode 34 is likely to occur.

The resistance change layer 12 is, for example, a metal oxide film and the protective film 72 is, for example, a metal film. For example, it is more difficult to etch the metal oxide film or the metal film than a silicon oxide film or a silicon nitride film. From this point of view, a connection failure between the memory bit line MBL and the source electrode 34 is likely to occur.

In the memory cell array 901 according to the comparative example, it is necessary to prevent the connection failure between the local bit line LBL and the source electrode 34 and it is difficult to reduce the size of the memory cell. The diameter of the bottom of the opening portion is reduced even in a case in which the length of the memory cell in any of the x direction and the y direction is reduced.

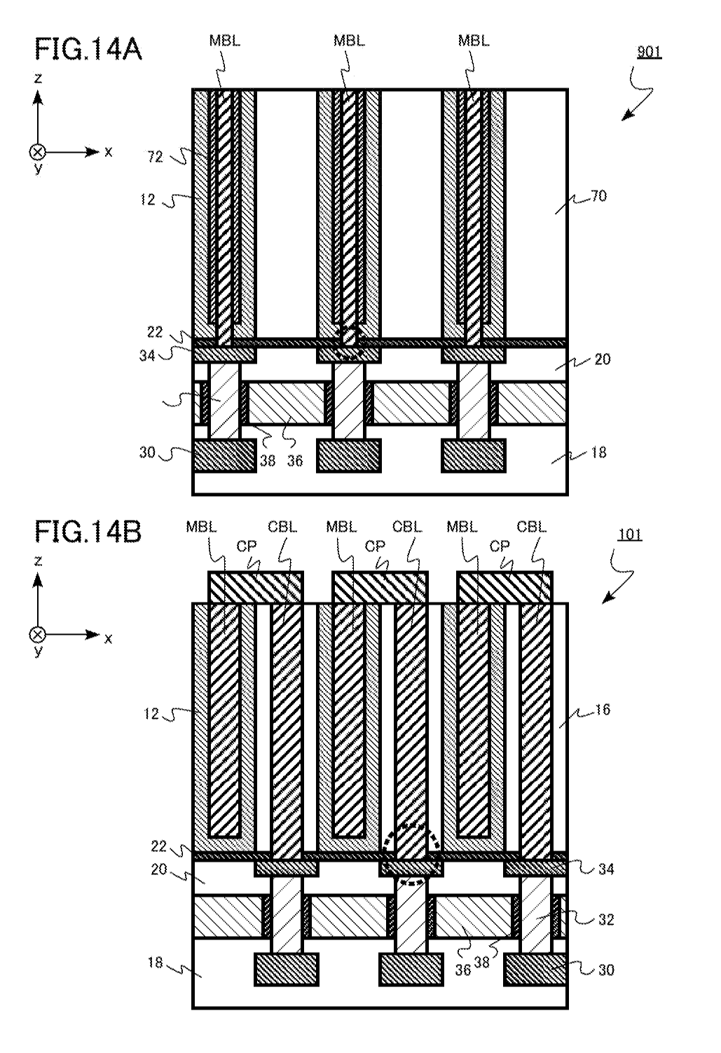

FIGS. 14A and 14B are diagrams illustrating the function and effect of the first embodiment. FIG. 14A is a cross-sectional view schematically illustrating the memory cell array 901 according to the comparative example and FIG. 14B is a cross-sectional view schematically illustrating the memory cell array 101 according to the first embodiment.

In the memory cell array 101 according to the first embodiment, the second end portion of the memory bit line MBL is not connected to the source electrode 34 unlike the memory cell array 901 according to the comparative example. The electrical connection between the source electrode 34 and the local bit line LBL is ensured by the connection between the second end portion of to connection bit line CBL and the source electrode 34. The resistance change layer 12 is not provided at the bottom of the opening portion 58 forming the connection bit line CBL (see FIG. 10B).

In this configuration, it is not necessary to provide the protective film 72 in a case in which the insulating film 60 located at the bottom of the opening portion 58 is removed. Therefore, the area of a connection portion (a region surrounded by a dashed line in FIG. 14B) between the connection bit line CBL and the source electrode 34 increases. As a result, a connection failure between the connection bit line CBL and the source electrode 34 is unlikely to occur.

In addition, since the aspect ratio of the opening portion 58 is lower than that in the memory cell array 901 according to the comparative example, a reduction in the etching rate of the insulating film 60 located at the bottom of the opening portion 58 is prevented. From this point of view, a connection failure between the connection bit line CBL and the source electrode 34 is unlikely to occur.

The insulating film 60 is, for example, a silicon oxide film that is easy to etch. From this point of view, a connection failure between the connection bit line CBL and the source electrode 34 is unlikely to occur.

In the memory cell array 101 according to the first embodiment, a connection failure between the local bit line LBL and the source electrode 34 is less likely to occur than that in the memory cell array 901 according to the comparative example. Therefore, it is easy to reduce the size of the memory cell. It is possible to reduce the length of the memory cell in any of the x direction and the y direction.

As described above, in the memory device 100 according to the first embodiment, the local bit line LBL is formed by the memory bit line MBL, the connection bit line CBL, and the connection portion CP. The connection between the local bit line LBL and the source electrode 34 of the selection transistor ST is ensured by the connection between the connection bit line CBL and the source electrode 34. Therefore, according to the memory device 100 of the first embodiment, it is possible to provide a memory device that can reduce the size of a memory cell.

### Second Embodiment

A memory device according to a second embodiment differs from the memory device according to the first embodiment in that the resistance change layer is provided between the second conductive layer and the third conductive layer and includes a first region provided between the first conductive layer and the third conductive layer and a second region which is provided between the second conductive layer and the third conductive layer and is separated from the first region. In addition, the memory device according to the second embodiment differs from the memory device according to the first embodiment in that the width of the fourth conductive layer in the first direction is larger than the width of the third conductive layer in the first direction. Hereinafter, the description of a portion of the same content as that in the first embodiment will not be repeated.

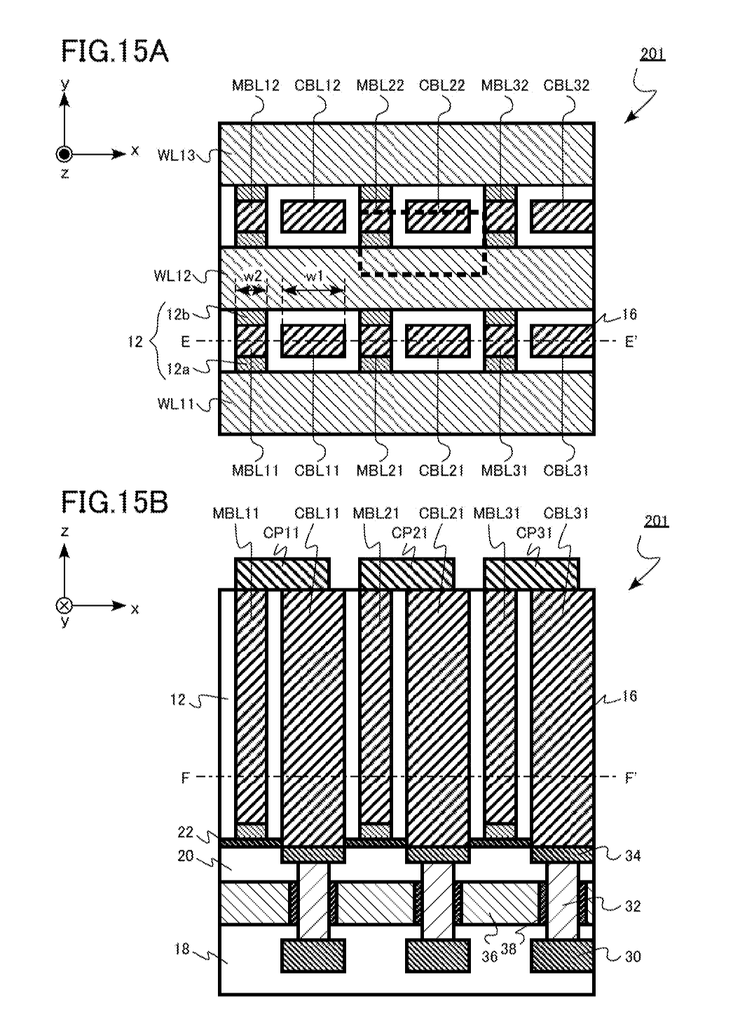

FIGS. 15A and 15B are cross-sectional views schematically illustrating a memory cell array 201 of the memory device according to the second embodiment. FIG. 15A is an xy cross-sectional view illustrating the memory cell array 201. FIG. 15B is an xz cross-sectional view illustrating the memory cell array 201. FIG. 15A is a cross-sectional view taken along the line FF′ of FIG. 15B and FIG. 15B is a cross-sectional view taken along the line EE′ of FIG. 15A. In FIG. 15A, a region surrounded by a dashed line corresponds to one unit cell of a memory cell.

The memory cell array 201 includes a word line WL11 (first conductive layer), a word line WL12 (second conductive layer), a word line WL13, memory bit line MBL11 (third conductive layer), a memory bit line MBL21 (fifth conductive layer), a memory bit line MBL31, a connection bit line CBL11 (fourth conductive layer), a connection bit line CBL21 (sixth conductive layer), a connection bit line CBL31, a connection portion CP11 (first connection portion), a connection portion CP21 (second connection portion), and a connection portion CP31. In addition, the memory cell array 201 includes a resistance change layer 12, a sidewall insulating layer 16, an interlayer insulating layer 18, an interlayer insulating layer 20, and a stopper film 22. Furthermore, the memory cell array 201 includes a drain electrode 30 (first electrode), a semiconductor layer 32, a source electrode 34 (second electrode), a gate electrode 36, and a gate insulating film 38.

The resistance change layer 12 includes a first region 12a and a second region 12b. For example, the first region 12a is provided between the word line WL11 and the memory bit line MBL11. The second region 12b is provided between the word line WL12 and the memory bit line MBL11. The first region 12a is separated from the second region 12b. The memory bit line MBL and the sidewall insulating layer 16 come into contact with each other.

The width of the connection bit line CBL in the x direction is larger than the width of the memory bit line MBL in the x direction. For example, the width (w1 in FIG. 15A) of the connection bit line CBL11 in the x direction is larger than the width (w2 in FIG. 15A) of the memory bit line MBL11 in the x direction.

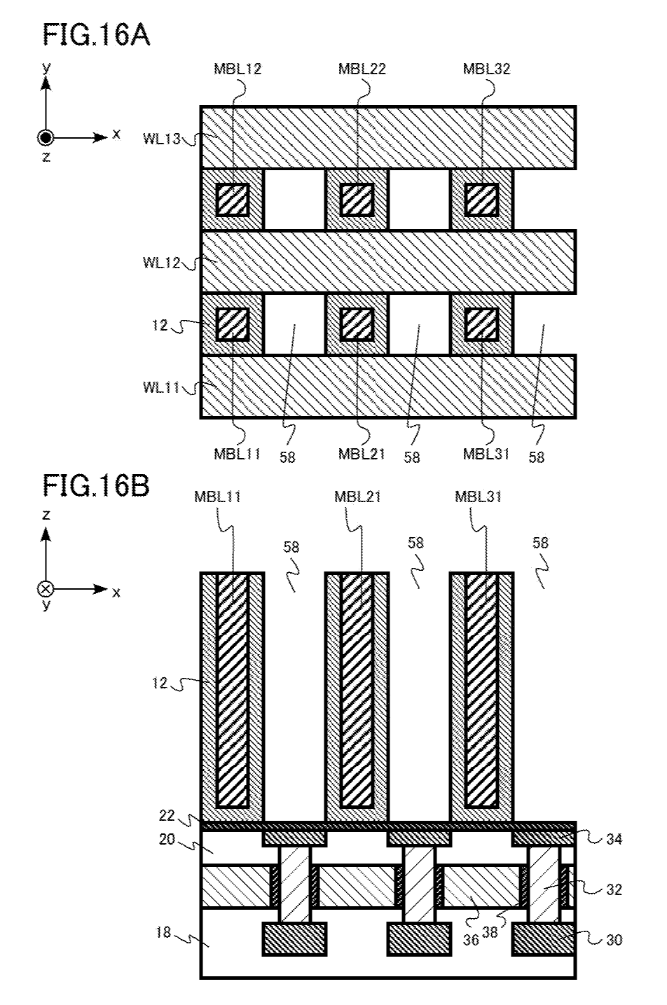

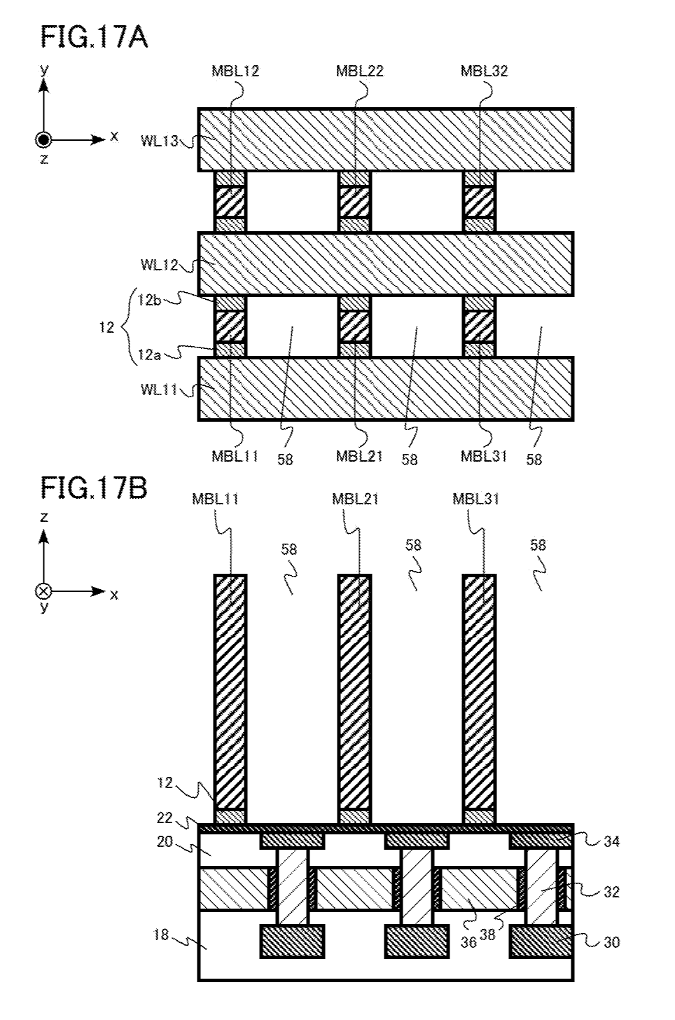

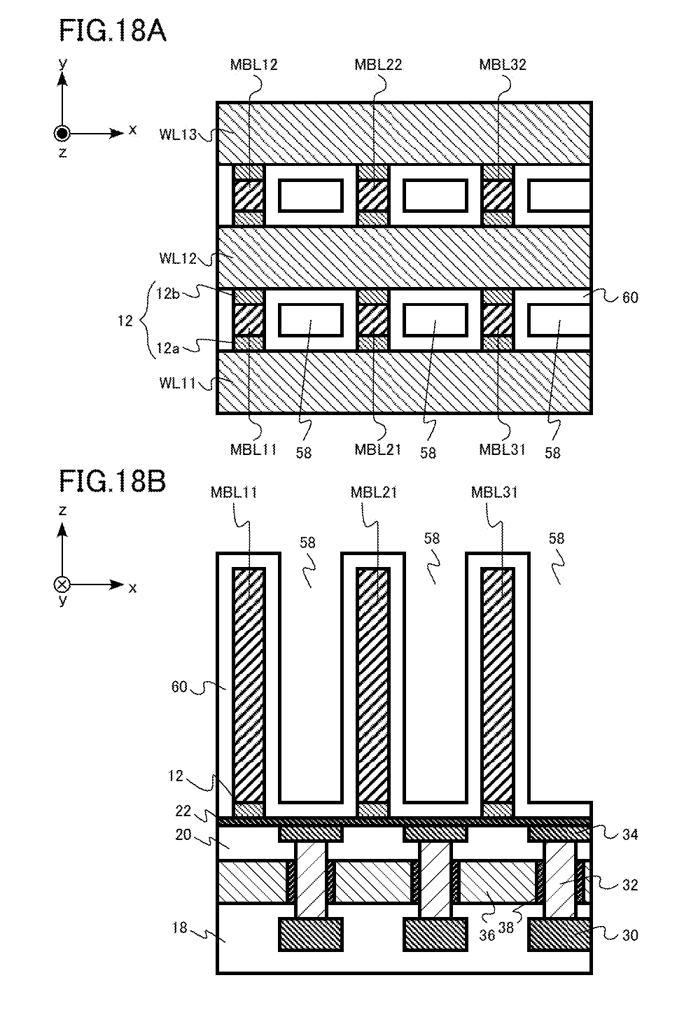

Next, a method for manufacturing the memory device according to the second embodiment will be described. FIG. 16A, FIG. 16B, FIG. 17A, FIG. 17B, FIG. 18A, and FIG. 18B are cross-sectional views schematically illustrating the memory device that is being manufactured in the memory device manufacturing method according to the second embodiment. FIG. 16A, FIG. 17A, and FIG. 18A are cross-sectional views illustrating the portion corresponding to FIG. 15A. FIG. 16B FIG. 17B, and FIG. 18B are cross-sectional views illustrating the portion corresponding to FIG. 15B.

The same process as that in the manufacturing method according to the first embodiment is performed until the sacrifice film 54 is etched to form the opening portions 58 (FIGS. 16A and 16B).

Then, the resistance change layer 12 in the opening portion 58 is isotropically removed (FIGS. 17A and 17B). A portion of the resistance change layer 12 around the memory bit line MBL is removed to form the first region 12a and the second region 12b that are separated from each other. The resistance change layer 12 is removed by, for example, wet etching or isotropic dry etching.

Then, the insulating film 60 is deposited in the opening portion 58 (FIGS. 18A and 18B). The insulating film 60 is made of, for example, silicon oxide. The insulating film 60 is deposited by, for example, a known CVD method.

Then, the memory cell array 201 of the memory device according to the second embodiment illustrated in FIGS. 15A and 15B is manufactured by the same manufacturing method as that in the first embodiment.

The size of the memory cell in the memory cell array 201 according to the second embodiment is equal to the size of the memory cell in the memory cell array 101 according to the first embodiment. However, the width of the connection bit line CBL in the x direction is larger than the width of the memory bit line MBL in the x direction. Therefore, the area of a connection portion between connection bit line CBL and the source electrode 34 is large. As a result, a connection failure between the local bit line LBL and the source electrode 34 is less likely to occur.

In addition, the first region 12a and the second region 12b of the resistance change layer 12 are separated from each other. Therefore, the interference between the memory cells that share the memory bit line MBL and are adjacent to each other in the y direction is unlikely to occur.

As described above, according to the memory device of the second embodiment, it is possible to provide a memory device that can reduce the size of a memory cell. In addition, a connection failure between the local bit line LBL and the source electrode 34 of the selection transistor, is prevented and it is possible to provide a memory device in which the interference between memory cells is prevented.

### Third Embodiment

A memory device according to a third embodiment differs from the memory device according to the second embodiment in that the width of the fourth conductive layer in the first direction is substantially equal to the width of the third conductive layer in the first direction. Hereinafter, the description of the same content as that in the first and second embodiments will not be repeated.

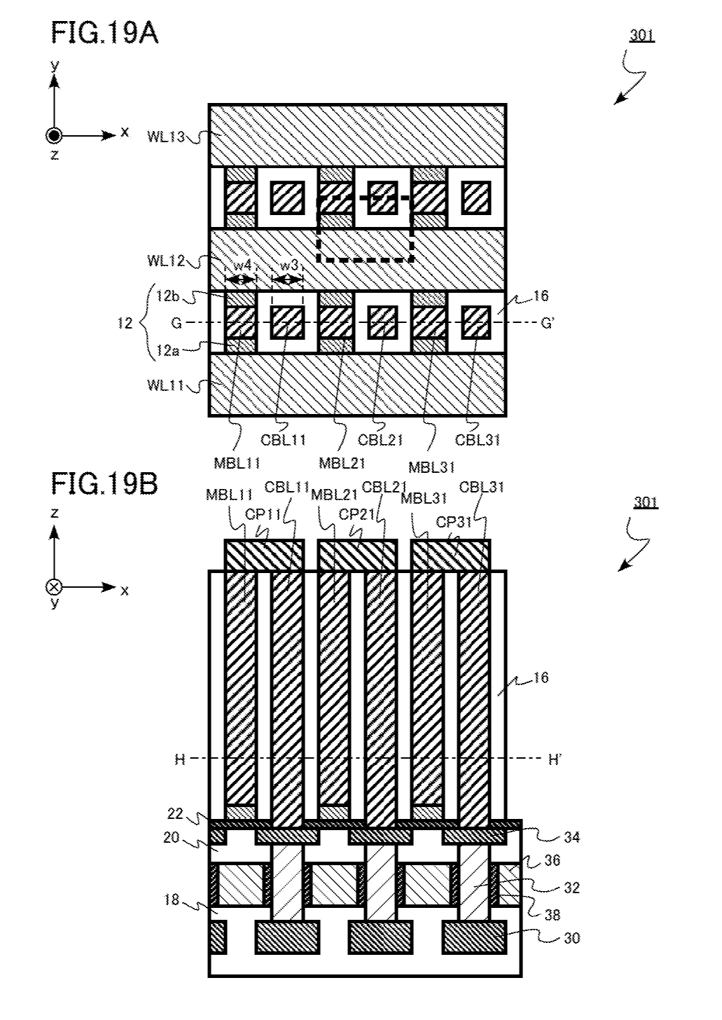

FIGS. 19A and 19B are cross-sectional views schematically illustrating a memory cell array 301 of a memory device according to the third embodiment. FIG. 19A is an xy cross-sectional view Illustrating the memory cell array 301. FIG. 19B is an xz cross-sectional view illustrating the memory cell array 301. FIG. 19A is a cross-sectional view taken along the line HH′ of FIG. 19B and FIG. 19B is a cross-sectional view taken along the line GG′ of FIG. 19A. In FIG. 19A, a region surrounded by a dashed line corresponds to one unit cell of a memory cell.

The memory cell array 301 includes a word line WL11 (first conductive layer), a word line WL12 (second conductive layer), a word line WL13, a memory bit line MBL11 (third conductive layer), a memory bit line MBL21 (fifth conductive layer), a memory bit line MBL31, a connection bit line CBL11 (fourth conductive layer), a connection bit line CBL21 (sixth conductive layer), connection bit line CBL31, a connection portion CP11 (first connection portion), a connection portion CP21 (second connection portion), and a connection portion CP31. In addition, the memory cell array 301 includes a resistance change layer 12, a sidewall insulating layer 16, an interlayer insulating layer 18, an interlayer insulating layer 20, and a stopper film 22. Furthermore, the memory cell array 301 includes a drain electrode 30 (first electrode) a semiconductor layer 32, a source electrode 34 (second electrode), a gate electrode 36, and a gate insulating film 38.

In the memory cell array 301, the width of the connection bit line CBL in the x direction is substantially equal to the width of the memory bit line MBL in the x direction. For example, the width (w3 in FIG. 19A) of the connection bit line CBL11 in the x direction is substantially equal to the width (w4 in FIG. 19A) of the memory bit line MBL11 in the x direction.

The memory device according to the third embodiment can be manufactured by reducing the pitch between the selection transistors ST in the x direction and the pitch between the opening portions for forming the memory bit lines MBL in the x direction and can be manufactured by the same manufacturing method as that in the second embodiment.

According to the memory device of the third embodiment, the length of the memory cell in the x direction is reduced. Therefore, the size of the memory cell is reduced.

As described above, according to the memory device of the third embodiment, it is possible to provide a memory device that can reduce the size of a memory cell.

While certain embodiments have been described, these embodiments have been presented by way of example only, and are not intended to limit the scope of the inventions. Indeed, the memory devices described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device comprising:
a first conductive layer extending in a first direction;
a second conductive layer extending in the first direction;
a third conductive layer extending in a second direction intersecting the first direction, the third conductive layer being provided between the first conductive layer and the second conductive layer;
a fourth conductive layer extending in the second direction, the fourth conductive layer being provided between the first conductive layer and the second conductive layer;
a first connection portion connecting a first end portion of the third conductive layer and a first end portion of the fourth conductive layer; and
a first resistance change layer provided between the first conductive layer and the third conductive layer.

2. The memory device according to claim 1, further comprising:
a first electrode;
a semiconductor layer provided between the first electrode and a second end portion of the fourth conductive layer;
a second electrode provided between the semiconductor layer and the second end portion of the fourth conductive layer, the second electrode being electrically connected to the second end portion of the fourth conductive layer;
a gate electrode; and
a gate insulating film provided between the semiconductor layer and the gate electrode.

3. The memory device according to claim 1, further comprising:
an insulating layer provided between the third conductive layer and the fourth conductive layer,
wherein the first resistance change layer is provided between the insulating layer and the third conductive layer.

4. The memory device according to claim 1,
wherein the first resistance change layer is provided between the second conductive layer and the third conductive layer, and
the first resistance change layer includes a first region provided between the first conductive layer and the third conductive layer and a second region provided between the second conductive layer and the third conductive layer, the second region being separated from the first region.

5. The memory device according to claim 4,
wherein a width of the fourth conductive layer in the first direction is larder than a width of the third conductive layer in the first direction.

6. The memory device according to claim 1, further comprising:
a fifth conductive layer extending in the second direction, the fifth conductive layer being adjacent to the fourth conductive layer in the first direction, the fifth conductive layer being provided between the first conductive layer and the second conductive layer;
a sixth conductive layer extending in the second direction, the sixth conductive layer being adjacent to the fifth conductive layer in the first direction, the sixth conductive layer being provided between the first conductive layer and the second conductive layer;
a second connection portion connecting a first end portion of the fifth conductive layer and a first end portion of the sixth conductive layer; and
a second resistance change layer provided between the first conductive layer and the fifth conductive layer.

7. The memory device according to claim 1,
wherein the first conductive layer and the second conductive layer are made of metal.

8. The memory device according to claim 1,
wherein the first resistance change layer includes metal oxide.

9. The memory device according to claim 2,
wherein the semiconductor layer is made of polysilicon.

10. The memory device according to claim 3,
wherein the insulating layer is made of silicon oxide.
